(19) United States
(12) Patent Application Publication
(10) Pub. No.: US 2011/0204758 A1
(43) Pub. Date: Aug. 25, 2011

(54) Electronic Device Securement System

(75) Inventors: Mark Loncar, San Francisco, CA (US); Luis G. Quehl, Santa Rosa, CA (US); Ryan Moore, Seattle, WA (US)

(73) Assignee: DayMen Photo Marketing LP, Markham, ON (CA)

(21) Appl. No.: 12/709,444

(22) Filed: Feb. 19, 2010

(51) Int. Cl. H05K 7/14; H05K 5/02

(52) U.S. Cl. 312/223.1; 248/224.8

(57) ABSTRACT

Embodiments hereof relate to an electronic device securement system for receiving and securing a portable electronic device to a protective housing. The electronic device is secured within the protective housing via a removable gasket, which is custom molded to stretch around the edges of the electronic device to receive the electronic device therein. The gasket is removably coupled to the protective housing via elastomeric protruding buttons of the gasket that frictionally engage holes formed in the protective housing. The electronic device securement system may include a closure strap. The closure strap may operate to transform the protective housing into an easel or stand for displaying the electronic device.

### FIELD OF THE INVENTION

The invention is related to an apparatus and method for securing an electronic device to or within a protective housing.

### BACKGROUND OF THE INVENTION

Portable or handheld electronic devices, such as eReader devices, personal digital assistants, cellular telephones, personal computers and the like, have internal circuitry and delicate componentry that are prone to damage that can occur when the electronic device is inadvertently dropped or impacted.

It is an object of the present invention to provide an electronic device securement system that protects the internal circuitry and delicate componentry of an electronic device from damage. In embodiments hereof, an elastomeric gasket removably secures any one of a number of differently-sized and/or type of electronic devices to a rigid protective housing. It is further an object of the present invention to provide an electronic device securement system that may be transformed from a case configuration that covers the electronic device received within the securement system into a stand or easel configuration that displays the electronic device received within the securement system.

### BRIEF SUMMARY OF THE INVENTION

Embodiments hereof relate to an electronic device securement system for connecting and securing an electronic device. In an embodiment hereof, the electronic device securement system includes a rigid protective housing having at least one hole formed therethrough and a soft elastomeric gasket that defines a storage compartment configured to receive the electronic device. The gasket includes at least one protruding elastomeric button that is configured to frictionally engage or compression fit into the at least one hole in order to removably couple the gasket to the protective housing.

In another embodiment hereof, the electronic device securement system includes a rigid protective housing having a front panel connected to a back panel via a spine in the manner of a book and a soft elastomeric gasket that defines a storage compartment configured to receive the electronic device. The gasket is removably coupled to the protective housing. The protective housing is operable to alternate between a case configuration to cover the gasket and the electronic device received therein and an easel configuration to display the gasket and electronic device received therein.

### BRIEF DESCRIPTION OF DRAWINGS

The foregoing and other features and advantages of the invention will be apparent from the following description of the invention as illustrated in the accompanying drawings. The accompanying drawings, which are incorporated herein and form a part of the specification, further serve to explain the principles of the invention and to enable a person skilled in the pertinent art to make and use the invention. The drawings are not to scale.

FIG. 1 is an illustration of an electronic device securement system according to an embodiment hereof.

FIG. 2 is a protective housing of the electronic device securement system of FIG. 1.

FIG. 3 is a front view of the protective housing of FIG. 2.

FIG. 4 is a back view of the protective housing of FIG. 2.

FIG. 5 is an enlarged view of a hole formed within the protective housing of FIG. 2.

FIG. 6 is a gasket of the electronic device securement system of FIG. 1.

FIG. 7 is a side view of the gasket of FIG. 6.

FIG. 8 is an enlarged view of a button of the gasket aligned within a hole formed within the protective housing according to an embodiment hereof.

FIG. 9 is an enlarged view of a button of the gasket compression fit into a hole formed within the protective housing according to an embodiment hereof.

FIG. 10 is a side view of the electronic device securement system of FIG. 1, wherein a closure strap according to an embodiment hereof is in a non-stretched open configuration.

FIG. 11 is a side view of the electronic device securement system of FIG. 1, wherein the closure strap is in a stretched closed configuration.

FIG. 12 is a perspective view of the electronic device securement system of FIG. 1, wherein the electronic device securement system is in an easel configuration.

FIG. 13 is an enlarged view of a portion of FIG. 12.

FIG. 14 is a perspective schematic illustration an electronic device securement system including a closure strap according to another embodiment hereof.

### DETAILED DESCRIPTION OF THE INVENTION

Specific embodiments of the present invention are now described with reference to the figures, wherein like reference numbers indicate identical or functionally similar elements. The following detailed description is merely exemplary in nature and is not intended to limit the invention or the application and uses of the invention. Although the description of the invention is in the context of securing electronic devices, the invention may also be used to secure other devices as it is deemed useful. Furthermore, there is no intention to be bound by any expressed or implied theory presented in the preceding technical field, background, brief summary or the following detailed description.

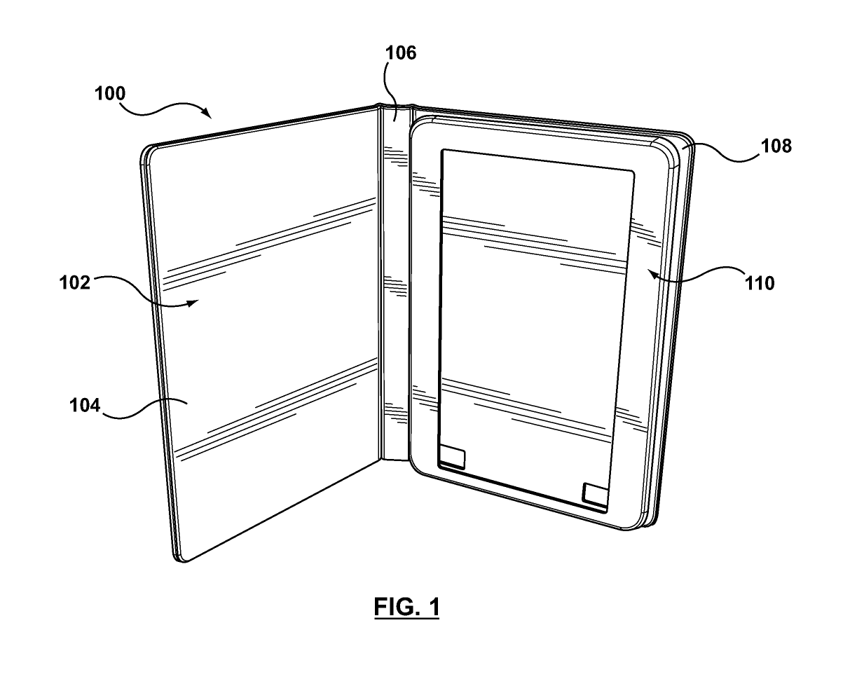

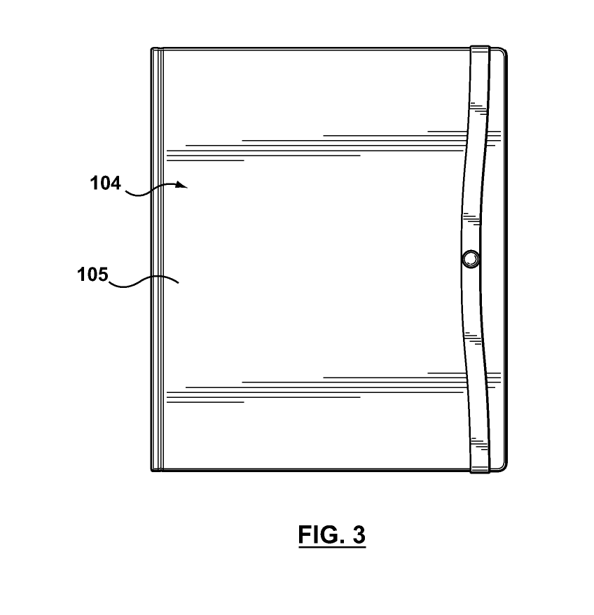

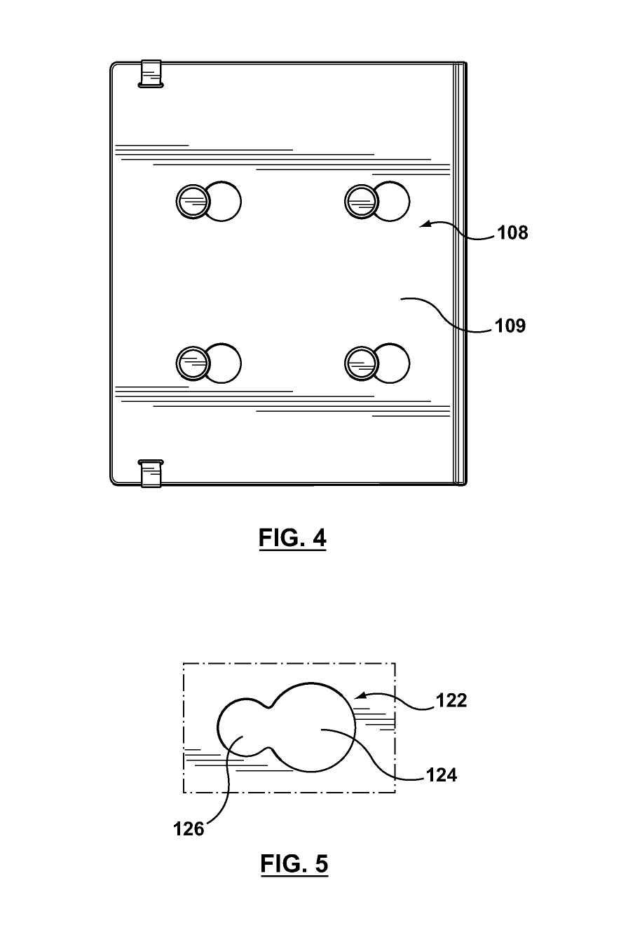

Embodiments hereof relate to an electronic device securement system 100 for connecting and securing an electronic device (not shown) to a protective housing 102 via a removable gasket 110. Protective housing 102 is formed from a relatively hard or rigid material that operates to shield the electronic device from breakage or damage. Protective housing 102 may be a cover, case, or other accessory configuration. In the embodiment depicted in FIGS. 1-6, housing 102 includes a first or front panel 104 connected to a second or back panel 108 via a spine 106 in the manner of a book. Gasket 110 is formed from a relatively soft elastomeric material that also operates to protect the electronic device from breakage or damage. Gasket 110 provides a unique form of protection by suspending the electronic device therein via its elastomeric material and connection mechanism to the rigid protection housing 102. Gasket 110 is removably coupled to back panel 108, and receives an electronic device within a storage compartment or open area 112 of gasket 110. Gasket 110 operates to secure the electronic device within protective housing 102 without requiring a mechanical device such as a clip, hinge, or other rigid connection. Electronic device securement system 100 thus utilizes both the relatively hard or rigid material of protective housing 102 and the soft elastomeric material of gasket 110 to provide secure attachment and unique protection of the electronic device. In one embodiment, electronic device securement system 100 is designed to receive an eBook reader such as the Kindle™. In another embodiment, electronic device securement system 100 is designed to retain and safely store any type of electronic device that may be fragile and prone to breakage. For example, the electronic device may be a mobile phone, a personal digital assistant (PDA), a tablet computer, a MP3 player, or other handheld portable electronic device.

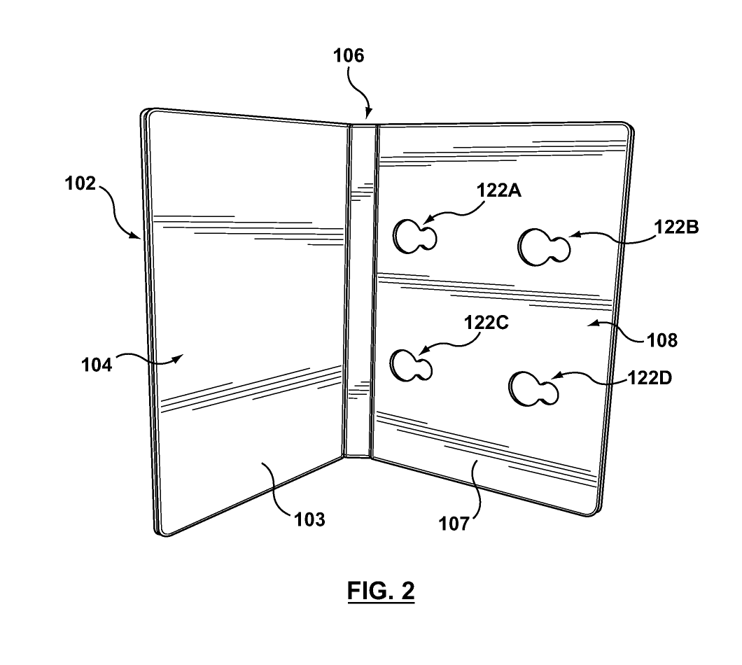

More particularly, referring to FIGS. 2-5, protective housing 102 is depicted without gasket 110 coupled thereto. Front panel 104 of housing 102 has a first outer or exterior surface 105 and a second inner or interior surface 103. Similarly, back panel 108 of housing 102 has a first outer or exterior surface 109 and a second inner or interior surface 107. As will be explained in more detail herein, back panel 108 includes at least one opening or hole 122 for coupling gasket 110 to housing 102. In the embodiment of FIGS. 1-5, back panel 108 includes four holes 122A, 122B, 122C, 122D. However, it will be understood to one of ordinary skill in the art that housing 102 may include any number of holes for coupling gasket 110 to housing 102. Holes 122 may be drilled or laser-cut through back panel 108 or formed by any other suitable method. In an embodiment, as shown in detail in FIG. 5, each hole 122 includes a first generally circular opening 124 and a second adjacent generally circular opening 126. First and second openings 124, 126 are continuous in that their perimeters intersect such that the openings are in communication with each other. First generally circular opening 124 has a larger diameter than second generally circular opening 126.

Panels 104 and 108, as well as spine 106, may be formed from any relatively hard or stiff protective material including but not limited to cardboard, bamboo, fiberboard, wood, wood fiber, metal, polymer, synthetic textiles, nylon, polyurethane, wool, polyester, and other suitable materials as would be known to those skilled in the art. In one embodiment, outer surfaces 105, 109 of panels 104, 108, respectively, may include a covering for aesthetic purposes. The covering may be canvas, cloth, synthetic leather, leather, or tarpaulin. Further, in one embodiment, inner surface 103 of front panel 104 may include an inner lining of a soft, non-scratch microfiber material and/or a thin padding of approximately 2-3 mm thickness between the lining and the hard protective material of front panel 104 to protect the electronic device when electronic device protective system 100 is closed.

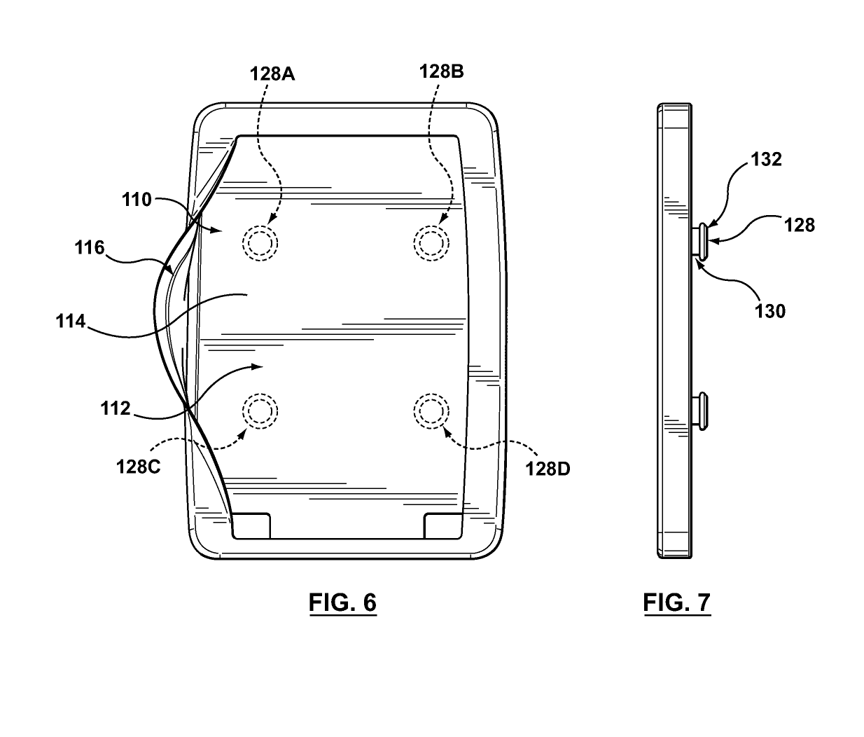

FIGS. 6 and 7 show gasket 110 removed from protective housing 102. Gasket 110 serves dual functions of receiving and protecting the electronic device within its elastomeric material, while simultaneously providing means for coupling the electronic device to protective housing 102. Gasket 110 is a molded skin or sleeve formed from silicone, urethane, rubber, thermoplastic elastomers (TPE), thermoplastic polyurethanes (TPU), or other moldable and stretchable compounds. Gasket 110 is custom molded to receive a particularly sized electronic device, and generally includes a back panel or backing 114 and a border 116 sized to securely fit around the edges of the electronic device. Backing 114 and border 116 define interior storage compartment 112, which has a volume suitable to contain the portable electronic device. When an electronic device is secured within gasket 110, border 116 does not obstruct full access to the front panel of the electronic device. Gasket 110 includes at least one protruding tab or button 128 transversely extending from backing 114 for coupling gasket 110 to housing 102. In the embodiment of FIG. 6, gasket 110 includes four buttons 128A, 128B, 128C, 128D corresponding to holes 122A, 122B, 122C, 122D of housing 102. However, it will be understood to one of ordinary skill in the art that gasket 110 may include any number of buttons corresponding to the number of holes within housing 102 for coupling the gasket and housing together. Each button 128 includes a generally cylindrical stem 130 and a cap 132. Each button 128 may be integrally formed with gasket 110, or may be attached to gasket 110.

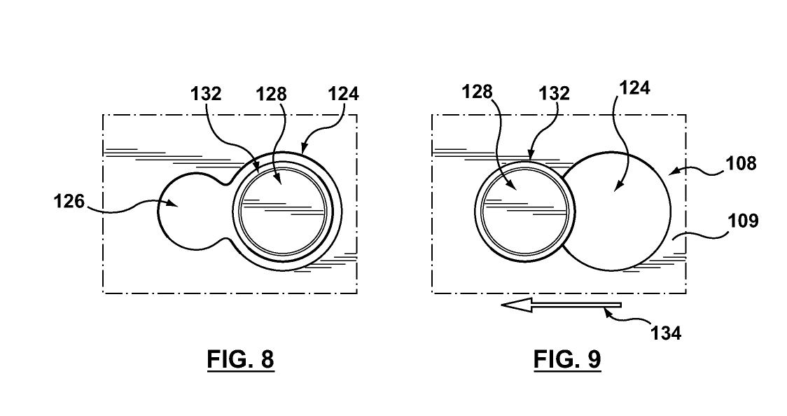

Referring now to FIGS. 8-9, gasket 110 is coupled to protective housing 102 via a snap-fit or interference connection between buttons 128 of gasket 110 received within corresponding holes 122 of protective housing 102. As shown in FIG. 8, each cap 132 of a corresponding button 128 is aligned with the first generally circular opening 124. Each first generally circular opening 124 is sized slightly larger than the corresponding cap 132 to allow cap 132 to be passed or inserted there through. Gasket 110 is then slid or translated in a direction indicated by arrow 134 such that button 128 snaps or locks into the adjacent, smaller second generally circular opening 126, as shown in FIG. 9. In particular, stem 130 has an outer diameter that is slightly larger than an inner diameter of the second opening 126. Thus, when gasket 110 is slid or translated in the direction of arrow 134, the outer surface of stem 130 frictionally engages the inner surface of opening 126. Stem 130 is preferably made from a relatively soft elastomeric material, for example a shore A50 durometer material, such that stem 130 deforms slightly and frictionally engages the inner surface of opening 126. Further, the outer surface of stem 130 may be textured or otherwise modified to provide additional friction.

In another embodiment, stem 130 of each button 128 may be slightly shorter than the thickness of back panel 108 such that the button is manually stretched or extended through the first generally circular opening 124 and slid into the second generally circular opening 126. Thus, in addition the frictional engagement of the outer surface of stem 130 with the inner surface of second opening 126, stem 130 tends to return to its unstretched configuration such that cap 132 abuts against exterior surface 109 of back panel 108 to supply compression and friction against back panel 108, thereby further securing gasket 110 and the electronic device secured therein to protective housing 102.

The combination of relatively stiff protective housing 102, relatively soft and compressible gasket 110, and the coupling mechanism coupling gasket 110 to housing 102 provide multiple forms of protection for the electronic device stored therein. Protective housing 102 provides protection from impact, while gasket 110 cushions or softens impact from housing 102 such that the impact force is reduced on the electronic device. Further, the coupling mechanism provides a secure connection to protective housing 102 while providing some give or movement of gasket 110 relative to housing 102 due to the configuration and the material used for buttons 128. The electronic device in gasket 110 is securely coupled the housing 102 but also “floats” relative to the housing 102. Accordingly, for example, if the securement system 100 is dropped on an edge thereof with the electronic device therein, the housing 102 will absorb the impact and the buttons 128 will reduce the transfer of such impact to the electronic device, thereby reducing the damage to the electronic device.

The frictional button connection between the gasket and the protective housing may be utilized with multiple gaskets having different sized storage compartments. More particularly, it may be desirable to utilize protective housing 102 for securing multiple electronic devices, each having a unique size and configuration. The gaskets are custom molded to receive a particular size electronic device, but elastomeric buttons 128 may be universally sized to be received within holes 122 of protective housing 102. Thus, since the gaskets are removable and interchangeable, one protective housing 102 may be universally used to secure several different electronic devices.

It would be understood by those skilled in the art that the openings 124, 126, stem 130, and cap 132, while described and shown as generally circular, need not be circular. These features can be oval, elliptical, square, rectangular, or other polygonal shape provided that they generally function in the manner described herein.

In addition to securing an electronic device to protective housing 102, the frictional button connection may be utilized to secure an electronic device received within gasket 100 into other items. For example, an easel, stand or frame that serves to display the electronic device may include holes 122 for accommodating buttons 128 of gasket 110. As a further example, a single panel, such as panel 108 may be used without a front panel. Panel 108 may instead, for example, include an extension substantially orthogonal to panel 108 such that panel 108 may stand on the extension. In another example, the extension may be c-shaped such that the panel can stand or be hung from the extension, for example, by a pocket in the rear of a car or airplane seat. Gasket 110 may be utilized to secure the electronic device to any relatively hard protective device that includes holes 122 for accommodating buttons 128 of gasket 110.

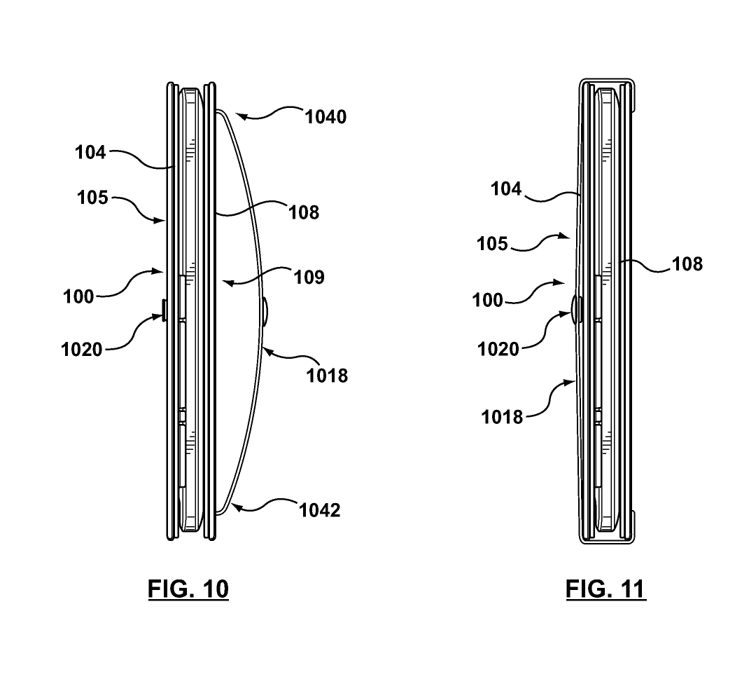

With reference to FIGS. 10 and 11, electronic device securement system 100 may include a closure strap 1018 that is operable to alternate between an open configuration shown in FIG. 10 and a closed configuration shown in FIG. 11. In one embodiment, closure strap 1018 is an elastic piece of material having a first end 1040 attached to a top portion of exterior surface 109 of back panel 108 and a second end 1042 attached to a bottom portion of exterior surface 109 of back panel 108. As shown in FIG. 10, when closure strap 1018 is in the open configuration front panel 104 and back panel 108 may be spread apart from each other in a manner similar to a book in order to access the electronic device located between panels 104, 108. Since closure strap 1018 is formed from an elastic material, closure strap 1018 may be stretched over exterior surface 105 of front panel 104 to encircle electronic device securement system 100 as shown in FIG. 11. The closed configuration of closure strap 1018 prevents front panel 104 and back panel 108 from being separated and prevents the electronic device located between panels 104, 108 from being unintentionally accessed.

In one embodiment, front panel 104 of electronic device securement system 100 may include a snap 1020 located thereon for securing closure strap 1018 in the closed configuration of FIG. 11. More particularly, a female component of snap 1020 is attached to front panel 104 and a mating male component of snap 1020 is attached to closure strap 1018. When closure strap 1018 is be stretched over front panel 104 to encircle electronic device securement system 100 as shown in FIG. 11, the female and male components of snap component 1020 are aligned and snapped together. Although described as having a female component attached to front panel 104 and a mating male component attached to closure strap 1018, it will be understood by those of ordinary skill in the art that the female component may be attached to closure strap 1018 and the mating male component may be attached to front panel 104.

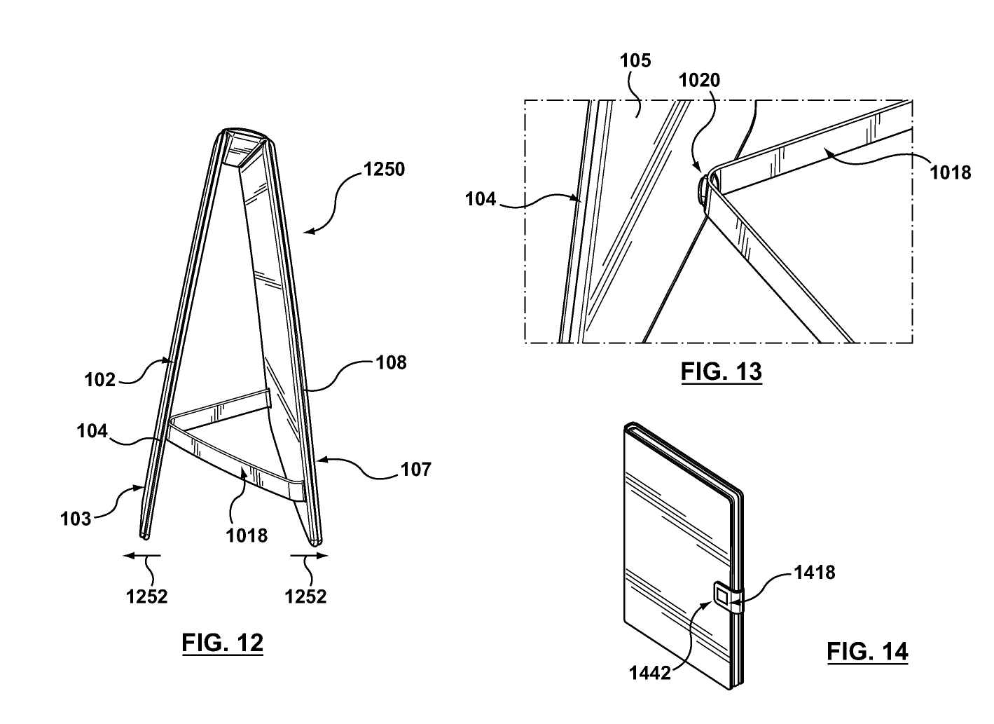

In addition to providing closure of electronic device securement system 100, closure strap 1018 and snap 1020 also collectively operate to transform protective housing 102 into an easel or stand 1250 as shown in FIGS. 12-13 for displaying the electronic device. For example, when electronic device securement system 100 is utilized for securing an eReader device, the user may use electronic device securement system 100 as a reading stand that does not require the user to hold the electronic device while the user watches/reads the contents displayed on the eReader in a landscape or horizontal mode. To convert protective housing 102 into easel 1250, front panel 104 is folded backwards such that interior surfaces 103, 107 of front panel 104 and back panel 108, respectively, face in an outward direction. Otherwise stated, electronic device securement system 100 is turned inside out. Closure strap 1018 is stretched to span across the gap between front panel 104 and back panel 108 and as best shown in FIG. 13, the female and male components of snap component 1020 are aligned and snapped together. Thus, the panels 104, 108, spine 106, and the surface upon which the panels sit form a triangle-like shape, and the strap 1018 connected to back panel 108 and snapped to front panel 104 counteracts the component of gravitational force acting in the direction of arrows 1252 to prevent housing 102 from collapsing.

In another embodiment, the closure strap may have an alternate configuration to provide closure of electronic device securement system 100. For example, as shown in FIG. 14, a closure strap 1418 may be a relatively short inelastic band of material having a first end attached to an intermediate portion of the exterior surface of the back panel (not shown). A second end 1442 of closure strap 1418 is unattached to electronic device securement system 100 when the electronic device securement system is open. To close electronic device securement system 100, closure strap 1418 extends from the back panel to the front panel and second end 1442 of closure strap 1418 is attached to a corresponding location on an intermediate portion of the exterior surface of the front panel. Closure strap 1418 may attach to the front panel via any appropriate method, including a snap, button, hook and loop fastener, magnetic attraction, or other mechanical method.

While various embodiments according to the present invention have been described above, it should be understood that they have been presented by way of illustration and example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the appended claims and their equivalents. It will also be understood that each feature of each embodiment discussed herein, and of each reference cited herein, can be used in combination with the features of any other embodiment. All patents and publications discussed herein are incorporated by reference herein in their entirety.

What is claimed is:

1. An electronic device securement system for connecting and securing an electronic device, the system comprising:
a rigid protective housing having at least one hole formed therethrough; and
a soft elastomeric gasket that defines a storage compartment configured to receive the electronic device, wherein the gasket includes at least one protruding elastomeric button that is configured to frictionally engage the at least hole in order to removably couple the gasket to the protective housing.

2. The system of claim 1, wherein the at least one hole includes a first opening intersecting an adjacent second opening, wherein the first opening is larger than the second opening.

3. The system of claim 2, wherein the first and second openings are generally circular and a first opening diameter is larger than a second opening diameter.

4. The system of claim 3, wherein the protruding button includes a stem and a cap, wherein the first opening diameter is slightly larger than a diameter of the cap and the second opening diameter is smaller than the diameter of the cap, and wherein the stem is generally cylindrical and includes a diameter larger than the second opening diameter and smaller than the first opening diameter and the cap diameter, wherein the protruding button is frictionally engaged into the at least one hole by passing the cap through the first opening and sliding the button into the second opening to frictionally engage an outer surface of the stem with an inner surface of the second opening.

5. The system of claim 2, wherein the protruding button includes a stem and a cap, wherein the first opening diameter is slightly larger the cap and the second opening is smaller than the cap, and wherein a cross-sectional dimension of the stem is larger than the second opening and smaller than the first opening and the cap, wherein the protruding button is frictionally engaged into the at least one hole by passing the cap through the first opening and sliding the button into the second opening to frictionally engage an outer surface of the stem with an inner surface of the second opening.

6. The system of claim 1, wherein the gasket includes a back panel and a border configured to stretch around edges of the electronic device.

7. The system of claim 1, wherein the at least one protruding button is integrally formed with the gasket.

8. The system of claim 1, wherein the gasket is custom molded and formed from silicone.

9. The system of claim 1, wherein the protective housing includes a front panel connected to a back panel via a spine in the manner of a book.

10. The system of claim 9, further comprising a closure strap that closes the electronic device securement system.

11. The system of claim 10, wherein the closure strap is an elastic piece of material having a first end attached to a top portion of an exterior surface of the back panel and a second end attached to a bottom portion of the exterior surface of the back panel.

12. The system of claim 11, wherein the front panel includes a snap for securing the closure strap.

13. An electronic device securement system for connecting and securing an electronic device, the system comprising:
a rigid protective housing having a front panel connected to a back panel via a spine in the manner of a book; and
a soft elastomeric gasket that defines a storage compartment configured to receive the electronic device, wherein the gasket is removably coupled to the protective housing,
wherein the protective housing is operable to selectively alternate between a case configuration to cover the gasket and the electronic device received therein and an easel configuration to display the gasket and electronic device received therein.

14. The system of claim 13, further comprising:
an elastic closure strap having a first end attached to a top portion of an exterior surface of the back panel and a second end attached to a bottom portion of the exterior surface of the back panel; and
a snap attached to an exterior surface of the front panel,
wherein the closure strap stretches over the exterior surface of the front panel and snaps into place when the protective housing is in the case configuration and wherein the closure strap stretches across a gap extending between the exterior surface of the front panel and the exterior surface of the back panel and snaps into place when the protective housing is in the easel configuration.

15. The system of claim 13, wherein the back panel of the protective housing has at least one hole formed therethrough and the gasket includes at least one protruding elastomeric button that is configured to frictionally engage the at least hole in order to removably couple the gasket to the protective housing.

16. The system of claim 15, wherein the at least one hole includes a first opening intersecting an adjacent second opening, wherein the first opening is larger than the second opening.

17. The system of claim 16, wherein the first and second openings are generally circular and a first opening diameter is larger than a second opening diameter.

18. The system of claim 17, wherein the protruding button includes a stem and a cap, wherein the first opening diameter is slightly larger than a diameter of the cap and the second opening diameter is smaller than the diameter of the cap, and wherein the stem is generally cylindrical and includes a diameter larger than the second opening diameter and smaller than the first opening diameter and the cap diameter, wherein the protruding button is frictionally engaged into the at least one hole by passing the cap through the first opening and sliding the button into the second opening to frictionally engage an outer surface of the stem with an inner surface of the second opening.

19. The system of claim 16, wherein the protruding button includes a stem and a cap, wherein the first opening diameter is slightly larger the cap and the second opening is smaller than the cap, and wherein a cross-sectional dimension of the stem is larger than the second opening and smaller than the first opening and the cap, wherein the protruding button is frictionally engaged into the at least one hole by passing the cap through the first opening and sliding the button into the second opening to frictionally engage an outer surface of the stem with an inner surface of the second opening.

20. The system of claim 13, wherein the gasket includes a back panel and a border configured to stretch around edges of the electronic device.
